(19) United States
(12) Patent Application Publication
(10) Pub. No.: US 2026/0363052 A1
(43) Pub. Date: Nov. 12, 2026

(54) INTERCONNECTION STRUCTURE AND METHODS OF FORMING THE SAME

(71) Applicant: TAIWAN SEMICONDUCTOR MANUFACTURING COMPANY, LTD., Hsinchu (TW)

(72) Inventors: Chin-Lung CHUNG, Taoyuan (TW); Meng-Pei LU, Hsinchu (TW); Ching-Fu YEH, Hsinchu (TW); Shin-Yi YANG, New Taipei (TW); Tsu-Chun KUO, Hsinchu (TW); Ming-Han LEE, Taipei (TW)

(21) Appl. No.: 19/295,621

(22) Filed: Aug. 10, 2025

Related U.S. Application Data
(60) Provisional application No. 63/800,488, filed on May 6, 2025.

(51) Int. Cl. H10W 20/41; H10W 20/00; H10W 20/42; H10W 20/44; H10D 30/00; H10D 62/10; H10D 84/83

(52) U.S. Cl. CPC H10W 20/425; H10W 20/065; H10W 20/076; H10W 20/082; H10W 20/42; H10W 20/435; H10W 20/4435; H10W 20/4446; H10D 30/502; H10D 62/121; H10D 84/832; H10W 20/072

(57) ABSTRACT

An interconnection structure, along with methods of forming such, are described. The interconnection structure includes a first dielectric layer disposed over a second dielectric layer, a first conductive feature disposed in the first dielectric layer, and a composite layer disposed between the first conductive feature and the first dielectric layer. The composite layer includes an alloy nitride.

### CROSS-REFERENCE TO RELATED APPLICATIONS

This application claims priority to US Provisional Application Serial No. 63/800,488 filed on May 6, 2025, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional side view of a stage of manufacturing a semiconductor device structure, in accordance with some embodiments.

FIG. 2 is a cross-sectional side view of a stage of manufacturing the semiconductor device structure, in accordance with some embodiments.

FIGS. 3A, 3B, 3C, 3C-1, 3C-2, 3C-3, 3D and 3E are cross-sectional side views of various stages of manufacturing the interconnection structure, in accordance with some embodiments.

FIGS. 4A and 4B are cross-sectional side views of various stages of forming a composite layer, in accordance with alternative embodiments.

FIGS. 5A and 5B are cross-sectional side views of various stages of forming the composite layer, in accordance with alternative embodiments.

FIGS. 6A, 6B and 6C are cross-sectional side views of various stages of manufacturing the interconnection structure, in accordance with alternative embodiments.

FIGS. 7A, 7B and 7C are cross-sectional side views of various stages of manufacturing the interconnection structure, in accordance with alternative embodiments.

FIGS. 8A, 8B and 8C are cross-sectional side views of various stages of manufacturing the interconnection structure, in accordance with alternative embodiments.

FIGS. 9A, 9B, 9C, 9D and 9E are cross-sectional side views of various stages of manufacturing the interconnection structure, in accordance with alternative embodiments.

FIGS. 10A, 10B and 10C are cross-sectional side views of various stages of manufacturing the interconnection structure, in accordance with alternative embodiments.

FIGS. 11A, 11B, 11C, 11D and 11E are cross-sectional side views of various stages of manufacturing the interconnection structure, in accordance with alternative embodiments.

FIGS. 12A, 12B and 12C are cross-sectional side views of various stages of manufacturing the interconnection structure, in accordance with alternative embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

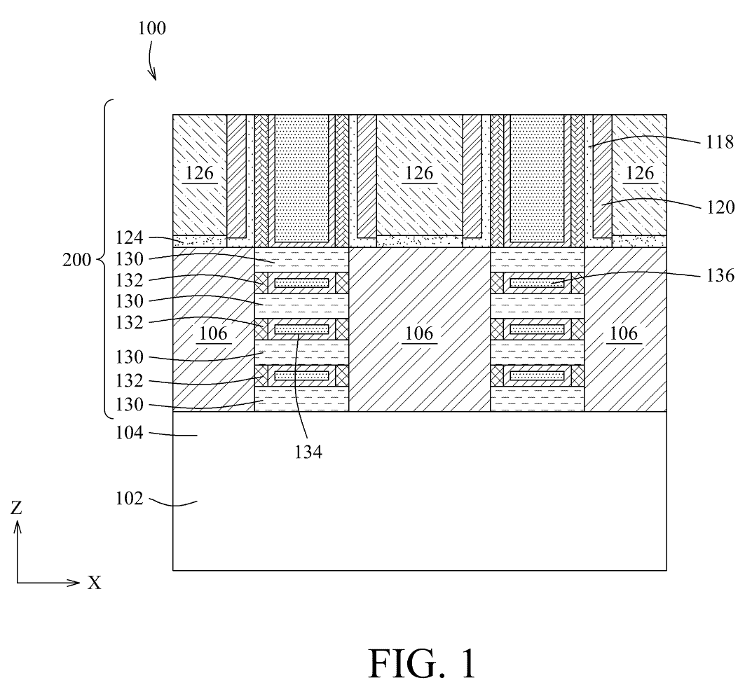

FIGS. 1 – 3E show exemplary processes for manufacturing a semiconductor device structure 100 according to embodiments of the present disclosure. It is understood that additional operations can be provided before, during, and after processes shown by FIGS. 1 – 3E, and some of the operations described below can be replaced or eliminated, for additional embodiments of the method. The order of the operations/processes is not limiting and may be interchangeable.

FIG. 1 illustrates a stage of manufacturing a semiconductor device structure 100. As shown in FIG. 1, the semiconductor device structure 100 includes a substrate 102 having substrate portions 104 extending therefrom and source/drain (S/D) regions 106 disposed over the substrate portions 104. The substrate 102 may be a semiconductor substrate, such as a bulk silicon substrate. In some embodiments, the substrate 102 may be an elementary semiconductor, such as silicon or germanium in a crystalline structure; a compound semiconductor, such as silicon germanium, silicon carbide, gallium arsenic, gallium phosphide, indium phosphide, indium arsenide, and/or indium antimonide; other suitable materials; or combinations thereof. Possible substrates 102 also include a silicon-on-insulator (SOI) substrate. SOI substrates are fabricated using separation by implantation of oxygen (SIMOX), wafer bonding, and/or other suitable methods. The substrate portions 104 may be formed by recessing portions of the substrate 102. Thus, the substrate portions 104 may include the same material as the substrate 102. The substrate 102 and the substrate portions 104 may include various regions that have been suitably doped with impurities (e.g., p-type or n-type impurities). The dopants are, for example boron for a p-type field effect transistor (PFET) and phosphorus for an n-type field effect transistor (NFET). The S/D regions 106 may include a semiconductor material, such as Si or Ge, a III-V compound semiconductor, a II-VI compound semiconductor, or other suitable semiconductor material. Exemplary S/D regions 106 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D regions 106 may include p-type dopants, such as boron; n-type dopants, such as phosphorus or arsenic; and/or other suitable dopants including combinations thereof. In this disclosure, a source region and a drain region are interchangeably used, and the structures thereof are substantially the same. Furthermore, source/drain region(s) may refer to a source or a drain, individually or collectively dependent upon the context.

As shown in FIG. 1, S/D regions 106 may be connected by one or more semiconductor layers 130, which may be channels of a FET. In some embodiments, the FET is a nanostructure FET including a plurality of semiconductor layers 130, and at least a portion of each semiconductor layer 130 is wrapped around by a gate electrode layer 136. The semiconductor layer 130 may be or include materials such as Si, Ge, SiC, GeAs, GaP, InP, InAs, InSb, GaAsP, AlInAs, AlGaAs, InGaAs, GaInP, GaInAsP, or other suitable material. In some embodiments, each semiconductor layer 130 is made of Si. The gate electrode layer 136 includes one or more layers of electrically conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. In some embodiments, the gate electrode layer 136 includes a metal. A gate dielectric layer 134 may be disposed between the gate electrode layer 136 and the semiconductor layers 130. The gate dielectric layer 134 may include two or more layers, such as an interfacial layer and a high-k dielectric layer. In some embodiments, the interfacial layer is an oxide layer, and the high-k dielectric layer includes hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), hafnium dioxide-alumina (HfO₂—Al₂O₃) alloy, or other suitable high-k materials.

The gate dielectric layer 134 and the gate electrode layer 136 may be separated from the S/D regions 106 by inner spacers 132. The inner spacers 132 may include a dielectric material, such as SiON, SiCN, SiOC, SiOCN, or SiN. Spacers 128 may be disposed over the plurality of semiconductor layers 130. The spacers 128 may include a dielectric material such as silicon oxide, silicon nitride, silicon carbide, silicon oxynitride, SiCN, silicon oxycarbide, SiOCN, and/or combinations thereof.

A contact etch stop layer (CESL) 118 and an interlayer dielectric (ILD) layer 120 are disposed over the S/D regions 106, as shown in FIG. 1. The CESL 118 may include an oxygen-containing material or a nitrogen-containing material, such as silicon nitride, silicon carbon nitride, silicon oxynitride, carbon nitride, silicon oxide, silicon carbon oxide, the like, or a combination thereof. The materials for the ILD layer 120 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

Conductive contacts 126 may be disposed in the ILD layer 120 and over the S/D regions 106, as shown in FIG. 1. The conductive contacts 126 may include one or more electrically conductive material, such as Ru, Mo, Co, Ni. W, Ti, Ta, Cu, Al, TiN and TaN. Silicide layers 124 may be disposed between the conductive contacts 126 and the S/D epitaxial features 106.

As shown in FIG. 1, the semiconductor device structure 100 may include the substrate 102 and a device layer 200 disposed over the substrate 102. The device layer 200 may include one or more devices, such as transistors, diodes, imaging sensors, resistors, capacitors, inductors, memory cells, combinations thereof, and/or other suitable devices. In some embodiments, the device layer 200 includes transistors, such as nanostructure transistors having a plurality of channels wrapped around by the gate electrode layer, as described above. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel(s) of the semiconductor device structure 100 may be surrounded by the gate electrode layer. The nanostructure transistors may be referred to as nanosheet transistors, nanowire transistors, gate-all-around (GAA) transistors, multi-bridge channel (MBC) transistors, or any transistors having the gate electrode layer surrounding the channels. In some embodiments, the device layer 200 includes devices such as planar FET, FinFET, complementary FET (CFET), forksheet FET, or other suitable devices.

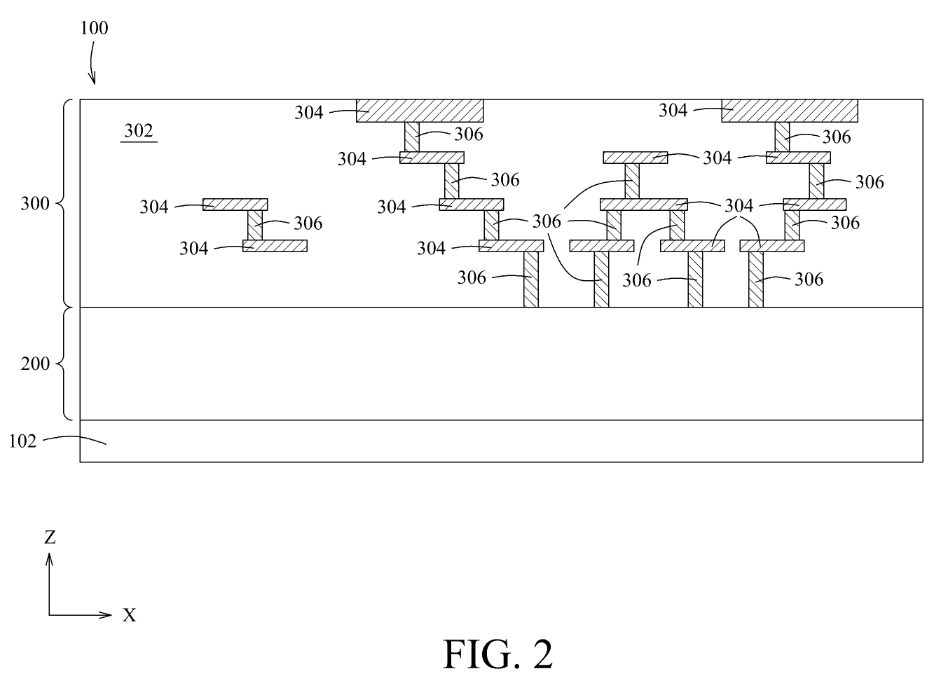

The semiconductor device structure 100 may further include an interconnection structure 300 disposed over the device layer 200 and the substrate 102, as shown in FIG. 2. The interconnection structure 300 includes various conductive features, such as a first plurality of conductive features 304 and second plurality of conductive features 306, and an intermetal dielectric (IMD) layer 302 to separate and isolate various conductive features 304, 306. In some embodiments, the first plurality of conductive features 304 are conductive lines and the second plurality of conductive features 306 are conductive vias. The interconnection structure 300 includes multiple levels of the conductive features 304, and the conductive features 304 are arranged in each level to provide electrical paths to various devices in the device layer 200 disposed below. The conductive features 306 provide vertical electrical routing from the device layer 200 to the conductive features 304 and between conductive features 304. For example, the bottom-most conductive features 306 of the interconnection structure 300 may be electrically connected to the conductive contacts 126 (FIG. 1) and the gate electrode layer 136 (FIG. 1). The conductive features 304 and conductive features 306 may be made from one or more electrically conductive materials, such as metal, metal alloy, metal nitride, or silicide. For example, the conductive features 304 and the conductive features 306 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof.

The IMD layer 302 includes one or more dielectric materials to provide isolation functions to various conductive features 304, 306. The IMD layer 302 may include multiple dielectric layers embedding multiple levels of conductive features 304, 306. In some embodiments, the IMD layer 302 includes a low-k dielectric material having a k value less than that of silicon oxide. In some embodiments, the IMD layer 302 includes SiOC, SiCₓN_{y}, BCₓN_{y}, SiOₓ, SiNₓ, SiCₓ, SiOₓC_{y}, SiOₓN_{y}, SiOₓC_{y}H_{z}, spin-on glass (SOG), amorphous fluorinated carbon, FSG, xerogel, aerogel, polyimide, parylene, bis-benzocyclobutenes, non-porous materials, or porous materials, where X and Y are integers or non-integers. The IMD layer 302 may be formed by chemical vapor deposition (CVD), atomic layer deposition (ALD), spin-on, physical vapor deposition (PVD) or other suitable process.

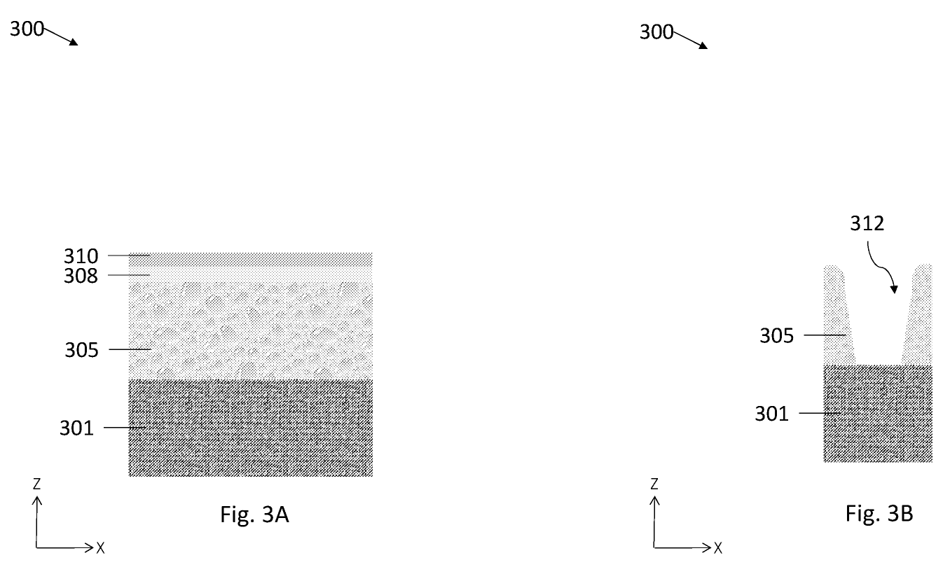

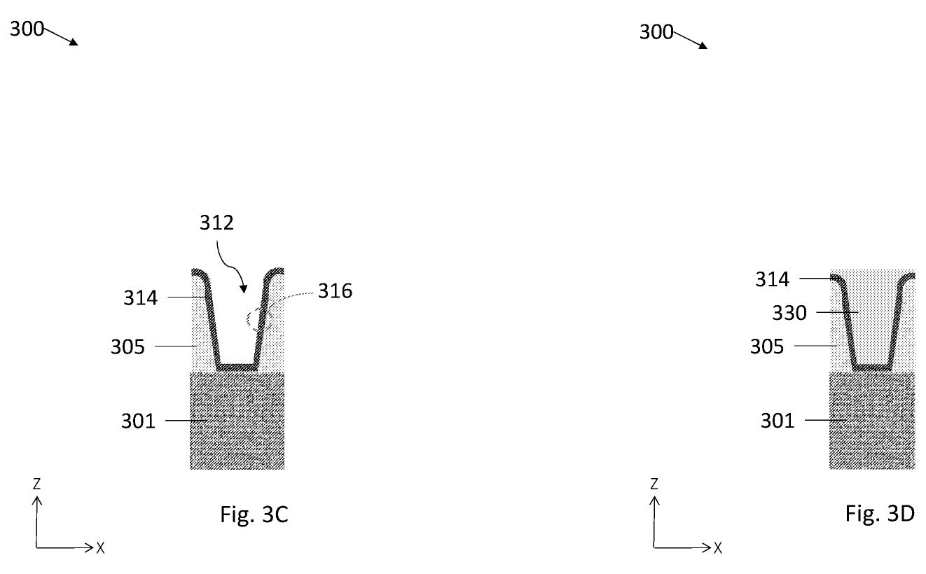

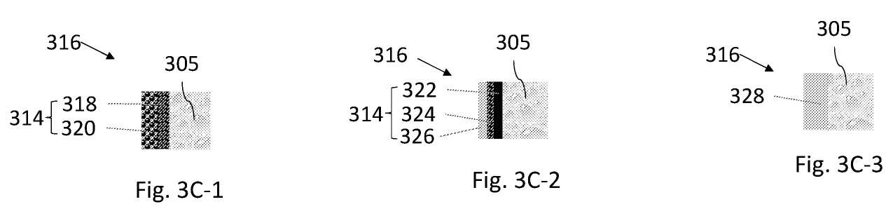

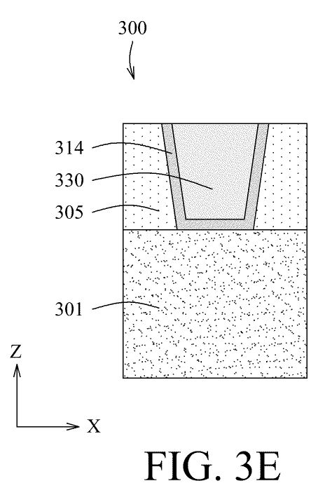

FIGS. 3A – 3E are cross-sectional side views of various stages of manufacturing the interconnection structure 300, in accordance with some embodiments. As shown in FIG. 3A, the interconnection structure 300 includes a dielectric layer 301, which may be an ILD layer or an IMD layer. For example, the dielectric layer 301 may be SiCOH and has a k value ranging from about 2.5 to about 3. In some embodiments, the dielectric layer 301 may be disposed over the ILD layer 120 (FIG. 1). The dielectric layer 301 may include one or more conductive features (not shown) disposed therein. The one or more conductive features may be electrically connected to the S/D regions 106 (FIG. 1) and the gate electrode layer 136 (FIG. 1). In some embodiments, the conductive features are the conductive features 304 or conductive features 306 shown in FIG. 2. The dielectric layer 301 may be formed by CVD, ALD, spin-on, PVD, or other suitable process.

As shown in FIG. 3A, a dielectric layer 305 is formed over the dielectric layer 301. The dielectric layer 305 may be an IMD layer 302 (FIG. 2). A hard mask layer 308 is formed on the dielectric layer 305, and a photoresist layer 310 is formed on the hard mask layer 308. The hard mask layer 308 may include any suitable dielectric material, such as SiN. The photoresist layer 310 may include one or more layers. In some embodiments, the photoresist layer 310 is a tri-layer photoresist layer including a bottom layer, a middle layer disposed on the bottom layer, and a resist layer disposed on the middle layer. The bottom layer may be a bottom anti-reflective coating (BARC). The bottom layer 214 may include organic materials. The middle layer may be formed from or include an inorganic material, which may be a nitride (such as silicon nitride), an oxynitride (such as silicon oxynitride), an oxide (such as silicon oxide), or the like. The resist layer is a photosensitive material. In some embodiments, the photoresist layer 310 formed over the hard mask layer 308 may be another type of photoresist, such as a single-layer photoresist, a bi-layer photoresist, or the like.

Next, as shown in FIG. 3B, an opening 312 is formed in the dielectric layer 305. The opening 312 may be formed by patterning the photoresist layer 310 and then transferring the pattern to the hard mask layer 308 and the dielectric layer 305. The photoresist layer 310 and the hard mask layer 308 may be removed during the formation of the opening 312 in the dielectric layer 305. In some embodiments, a conductive feature (not shown) formed in the dielectric layer 301 is exposed at the bottom of the opening 312. In some embodiments, the dielectric layer 301 is exposed at the bottom of the opening 312.

As shown in FIG. 3C, a composite layer 314 is formed in the opening 312. In some embodiments, the composite layer 314 is a single layer and includes an alloy nitride, such as CoNbN, TaNbN, RuNbN, CoTaN, CoTaNbN, CoRuNbN, CoRuTaN, CoZrN, CoVN, or combinations thereof. In some embodiments, the alloy nitride is a nitride of two or more metals. The composite layer 314 including alloy nitride can function as both a barrier layer and an adhesion layer. In some embodiments, the subsequently formed conductive feature 330 (FIG. 3E) may include a metal, such as Cu, that is susceptible to diffusion, and the composite layer 314 may prevent metal diffusion from the conductive feature 330 to the dielectric layer 305. Furthermore, the composite layer 314 can improve the adhesion of the conductive feature 330 and the dielectric layer 305. In some embodiments, the thickness of the single composite layer 314 may range from about 5 angstroms to about 50 angstroms. The thickness of the single composite layer 314 is less than a combined thickness of a conventional barrier layer and a conventional adhesion layer. With the smaller thickness of the composite layer 314, the dimensions of the conductive feature 330 are increased. The electrical resistance of the conductive feature 330 is less than the electrical resistance of the composite layer 314. Thus, the electrical resistance in the interconnection structure 300 is reduced. In some embodiments, the thickness of the composite layer 314 is less than about 5 angstroms, the ability for preventing diffusion of the metal may be adversely affected. On the other hand, if the thickness of the composite layer 314 is greater than about 50 angstroms, the volume of the conductive feature 330 is reduced, leading to increased electrical resistance.

The alloy nitride layer of the composite layer 314 may be deposited by any suitable method. In some embodiments, the alloy nitride layer is deposited by PVD, CVD, ALD, wet coating, electroplating, other suitable process, or combinations thereof. The deposition temperature may range from about 20 degrees Celsius to about 400 degrees Celsius.

In some embodiments, the composite layer 314 includes two or more layers. FIGS. 3C-1 to FIGS. 3C-3 illustrate a portion 316 of the interconnection structure 300 of FIG. 3C. In some embodiments, the composite layer 314 is a bilayer structure and includes a first layer 318 formed on the dielectric layer 305 and a second layer 320 formed on the first layer 318, as shown in FIGS. 3C-1. In some embodiments, the combined thickness of the first and second layers 318, 320 ranges from about 5 angstroms to about 50 angstroms. In some embodiments, the first layer 318 includes the alloy nitride described in FIG. 3C, and the second layer 320 includes an alloy. The alloy includes two or more metals, such as CoNb, RuTa, CoTa, CoTaNb, CoRuNb, CoRuTa, CoV, CoZr, or RuTa. In some embodiments, the first layer 318 includes the alloy, and the second layer 320 includes the alloy nitride. In some embodiments, the first layer 318 includes the alloy nitride, and the second layer 320 includes a metal, such as Co, Ta, Ru, Zr. The metal of the second layer 320 may be different from the metal of the subsequently formed conductive feature 330. In some embodiments, the first layer 318 includes a metal nitride, and the second layer 320 includes the alloy nitride. The metal nitride may include TaN, NbN, CoN, or ZrN. In some embodiments, the metal nitride is nitride of a single metal.

In some embodiments, one of the first and second layers 318, 320 includes the alloy nitride, and the other of the first and second layers 318, 320 includes the metal, the alloy, or the metal nitride. The bilayer structure of the composite layer 314 may have improved barrier property compared to the single layer composite layer 314. The arrangements of the first and second layers 318, 320 may enhance the adhesion of the conductive feature 330 and the dielectric layer 305. For example, in some embodiments, the metal or the alloy has better adhesion to the conductive feature 330 compared to the alloy nitride. As a result, the second layer 320 includes the metal or the alloy, and the first layer 318 includes the alloy nitride. The second layer 320 is disposed between the first layer 318 and the conductive feature 330. In some embodiments, the alloy nitride has better adhesion to the conductive feature 330 compared to the metal nitride. As a result, the second layer 320 includes the alloy nitride, and the first layer 318 includes the metal nitride.

In some embodiments, the first and second layers 318, 320 are deposited by a single process. For example, the first and second layers 318, 320 may be deposited by a PVD process, in which two or more sputtering targets are used. For example, the first layer 318 may include the alloy nitride, and the second layer 320 includes a metal. In such embodiment, a first sputtering target includes a first metal, and a second sputtering target includes a metal nitride. During the PVD process, the first and second sputtering target may be utilized for a first period of time, and the alloy nitride is deposited. Then, the second sputtering target may be removed from the PVD process, and the first sputtering target is utilized for a second period of time. As a result, the metal layer is deposited on the alloy nitride layer. Because the metal layer and the alloy nitride layer are formed by the single PVD process, there may not be a distinct interface between the metal layer and the alloy nitride layer. The first and second periods of time may be adjusted to control the thicknesses of the first and second layers. In some embodiments, the first and second periods of time are the same. In some embodiments, the first and second periods of time are different. The order of the sputtering targets being used may be also switched, and the first layer 318 includes the metal, and the second layer 320 includes the alloy nitride. In some embodiments, the first sputtering target includes an alloy, and the first or second layer 318, 320 may include the alloy.

In some embodiments, a CVD process is performed to form the first and second layers 318, 320. During the CVD process, a nitrogen-containing precursor, a first metal-containing precursor, and a second metal-containing precursor may be introduced into the processing chamber for a first period of time to deposit the first layer 318, which may be an alloy nitride layer. Then, the nitrogen-containing precursor is stopped, while the first and/or second metal-containing precursors continue to flow into the processing chamber for a second period of time to deposit the second layer 320, which may be an alloy layer or a metal layer on the alloy nitride layer. Similarly, because the alloy layer and the alloy nitride layer are formed by the single CVD process, there may not be a distinct interface between the alloy layer and the alloy nitride layer. The first and second periods of time may be adjusted to control the thicknesses of the first and second layers 318, 320. In some embodiments, the first and second periods of time are the same. In some embodiments, the first and second periods of time are different. The order of the precursors being flowed into the processing chamber may be changed to form the corresponding first and second layers 318, 320.

In some embodiments, the composite layer 314 includes multiple layers, as shown in FIG. 3C-2. For example, the composite layer 314 includes a first layer 322 disposed on the dielectric layer 305, a second layer 324 disposed on the first layer 322, and a third layer 326 disposed on the second layer 324. In some embodiments, one of the first, second, and third layers 322, 324, 326 includes the alloy nitride, and the other two of the first, second, and third layers 322, 324, 326 include the metal, the alloy, the metal nitride, or combinations thereof. For example, in some embodiments, the first layer 322 includes the metal nitride, the second layer 324 includes the alloy nitride, and the third layer 326 includes the metal. In some embodiments, the first layer 322 includes the metal nitride, the second layer 324 includes the alloy nitride, and the third layer 326 includes the alloy. In some embodiments, the first layer 322 includes the alloy nitride, the second layer 324 includes the metal nitride, and the third layer 326 includes the metal. In some embodiments, the first layer 322 includes the alloy nitride, the second layer 324 includes the metal nitride, and the third layer 326 includes the alloy. In some embodiments, the first layer 322 includes the alloy, the second layer 324 includes the alloy nitride, and the third layer 326 includes the metal. In some embodiments, the first layer 322 includes the alloy, the second layer 324 includes the alloy nitride, and the third layer 326 includes the alloy. In some embodiments, the first layer 322 includes the alloy nitride, the second layer 324 includes the alloy, and the third layer 326 includes the metal. In some embodiments, the first layer 322 includes the alloy nitride, the second layer 324 includes the metal, and the third layer 326 includes the alloy.

Similar to the arrangements of the first and second layers 318, 320, the arrangements of the first, second, and third layers 322, 324, 326 can lead to improved barrier and adhesion properties. In some embodiments, the total thickness of the first, second, and third layers 322, 324, 326 ranges from about 5 angstroms to about 50 angstroms. In some embodiments, the individual layers of the first and second layers 318, 320 or the first, second, and third layers 322, 324, 326 are deposited by distinct processes. For example, the first layer 318 is deposited by a first process, and the second layer 320 is deposited by a second process different from the first process.

In some embodiments, the composite layer 314 includes a gradient layer 328, as shown in FIG. 3C-3. In some embodiments, the gradient layer 328 includes the alloy nitride having a gradient nitrogen concentration. For example, the nitrogen concentration changes in a direction away from the dielectric layer 305. In some embodiments, the nitrogen concentration in the gradient layer 328 may decrease in the direction away from the dielectric layer 305. In some embodiments, a high nitrogen concentration improves barrier property, while a low nitrogen improves adhesion property.

As shown in FIG. 3D, the conductive feature 330 is deposited in the opening 312 on the composite layer 314. The conductive feature 330 may include an electrically conductive material, such as copper (Cu), silver (Ag), gold (Au), aluminum (Al), nickel (Ni), cobalt (Co), ruthenium (Ru), iridium (Ir), platinum (Pt), palladium (Pd), osmium (Os), tungsten (W), molybdenum (Mo), tantalum (Ta), graphene, or other suitable materials. In some embodiments, the conductive feature 330 includes one or more metals. The conductive feature 330 may be formed by any suitable process, such as PVD, CVD, electroplating, electroless plating, or ALD.

Next, as shown in FIG. 3E, a planarization process, such as a CMP process, is performed to remove portions of the conductive feature 330 and composite layer 314 formed on the dielectric layer 305. As a result, the dielectric layer 305 is exposed.

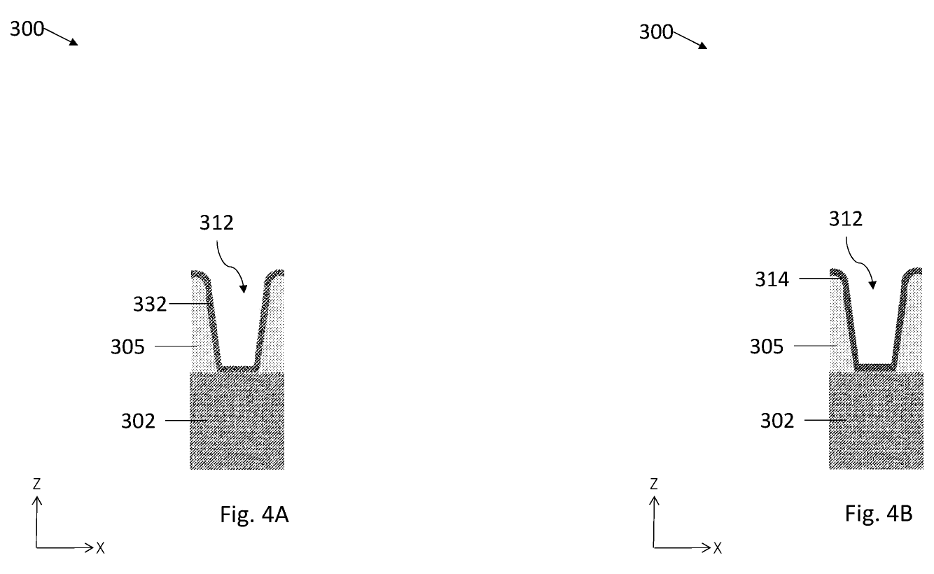

FIGS. 4A and 4B are cross-sectional side views of various stages of forming the composite layer 314, in accordance with alternative embodiments. As shown in FIG. 4A, an alloy layer 332 is first deposited in the opening 312. The alloy layer 332 may include two or more metals. In some embodiments, the alloy layer 332 includes CoNb, RuTa, CoTa, CoTaNb, CoRuNb, CoRuTa, CoV, CoZr, or RuTa. The alloy layer 332 may be deposited by any suitable process, such as PVD, CVD, ALD, wet coating, or electroplating. The deposition temperature may range from about 20 degrees Celsius to about 400 degrees Celsius.

Next, as shown in FIG. 4B, a treatment process is performed on the alloy layer 332 to form the composite layer 314. The treatment process may be a nitridation process. The treatment process may include a plasma based process (e.g., an inductively coupled plasma (ICP) process, a microwave-assisted plasma process, a capacitively coupled plasma (CCP) process), an ion beam bombardment process, or other suitable process. The treatment process may utilize a nitrogen-containing gas, such as N₂, N₂O, NO, other suitable nitrogen-containing gas, or combinations thereof. In some embodiments, the alloy layer 332 is completely nitridated, and the resulting composite layer 314 includes nitrogen throughout the thickness of the composite layer 314. In some embodiments, the nitrogen concentration decreases in a direction from the opening 312 to the dielectric layer 305 as a result of the treatment process, and the composite layer 314 is the gradient layer 328 described in FIG. 3C-2.

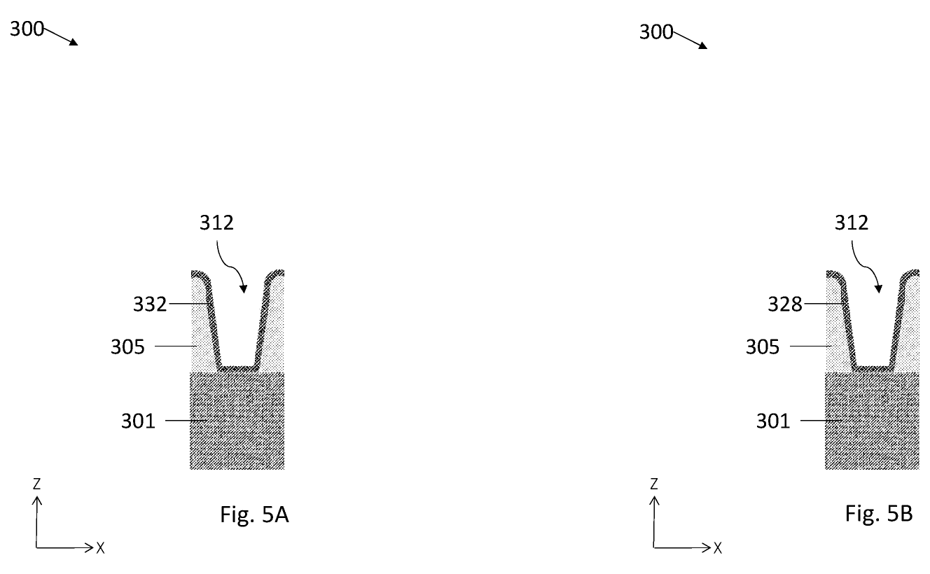

FIGS. 5A and 5B are cross-sectional side views of various stages of forming the composite layer 314, in accordance with alternative embodiments. As shown in FIG. 5A, the alloy layer 332 is deposited in the opening 312 on the dielectric layer 305. Next, the treatment process is performed to partially nitridate the alloy layer 332 to form the gradient layer 328, as shown in FIG. 5B. As a result, the gradient layer 328 includes an alloy nitride layer having a nitrogen concentration decreasing in a direction away from the dielectric layer 305.

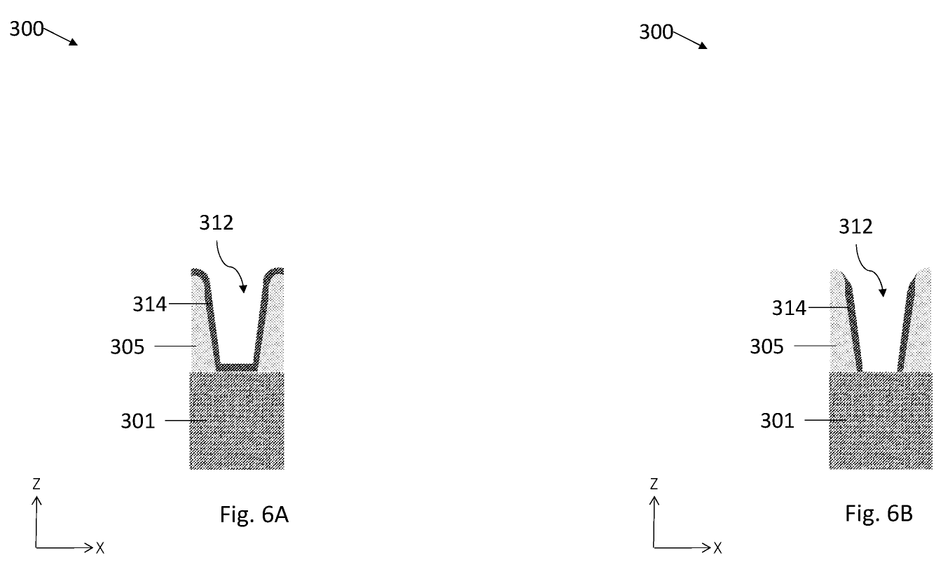

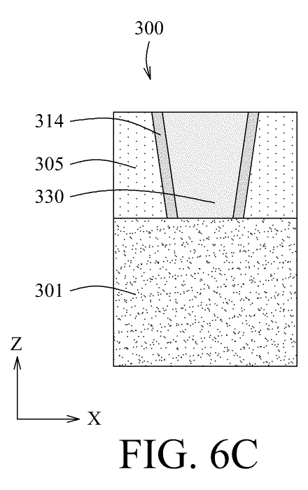

FIGS. 6A, 6B and 6C are cross-sectional side views of various stages of manufacturing the interconnection structure 300, in accordance with alternative embodiments. As shown in FIG. 6A, the composite layer 314 is formed in the opening 312 on the dielectric layer 305. Next, an etch process is performed to remove portions of the composite layer 314 formed on horizontal surfaces, as shown in FIG. 6B. The etch process may be an anisotropic etch process. As a result, the dielectric layer 301 (and/or the conductive feature formed in the dielectric layer 301) is exposed at the bottom of the opening 312. Furthermore, the etch process is a selective etch process that does not substantially remove the dielectric layers 301, 305. Next, as shown in FIG. 6C, the conductive feature 330 is formed in the opening 312. In some embodiments, the conductive feature 330 is in contact, or interfaces, the conductive feature (not shown) formed in the dielectric layer 301, and the contact resistance is reduced.

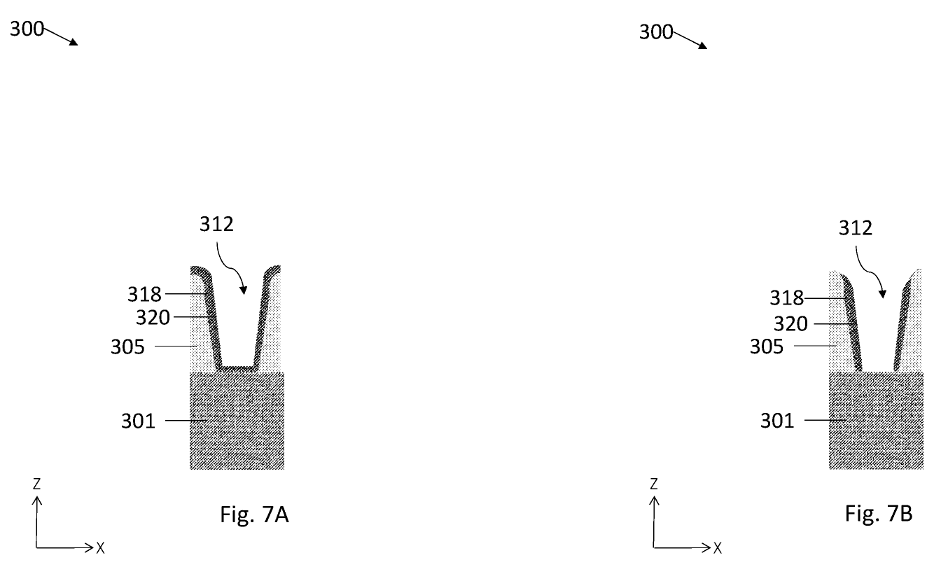

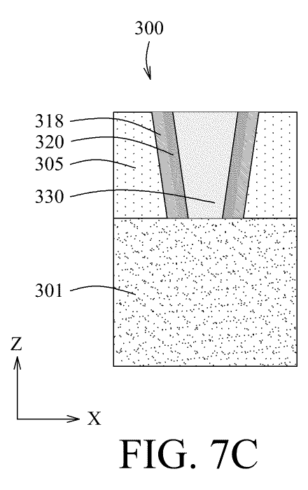

FIGS. 7A, 7B and 7C are cross-sectional side views of various stages of manufacturing the interconnection structure 300, in accordance with alternative embodiments. As shown in FIG. 7A, the first and second layers 318, 320 are formed in the opening 312 on the dielectric layer 305. In some embodiments, the second layer 320 includes the alloy nitride exposed in the opening 312 and the first layer 318 includes the alloy interfacing the dielectric layer 305. Next, one or more etch processes are performed to remove portions of the first and second layers 318, 320 formed on horizontal surfaces, as shown in FIG. 7B. The one or more etch processes may be anisotropic etch processes. For example, in some embodiments, a first anisotropic etch process is performed to remove portions of the second layer 320 formed on the horizontal surfaces, and a second anisotropic etch process is performed to remove portions of the first layer 318 formed on the horizontal surfaces. The first and second anisotropic etch processes are selective etch processes. The first anisotropic etch process does not substantially affect the first layer 318, and the second anisotropic etch process does not substantially affect the second layer 320 and the dielectric layers 301, 305. In some embodiments, a single anisotropic etch process is performed to remove the portions of the first and second layers 318, 320. After the one or more etch processes, the dielectric layer 301 (and/or the conductive feature formed in the dielectric layer 301) is exposed at the bottom of the opening 312. Next, as shown in FIG. 7C, the conductive feature 330 is formed in the opening 312. In some embodiments, the conductive feature 330 is in contact, or interfaces, the conductive feature (not shown) formed in the dielectric layer 301, and the contact resistance is reduced.

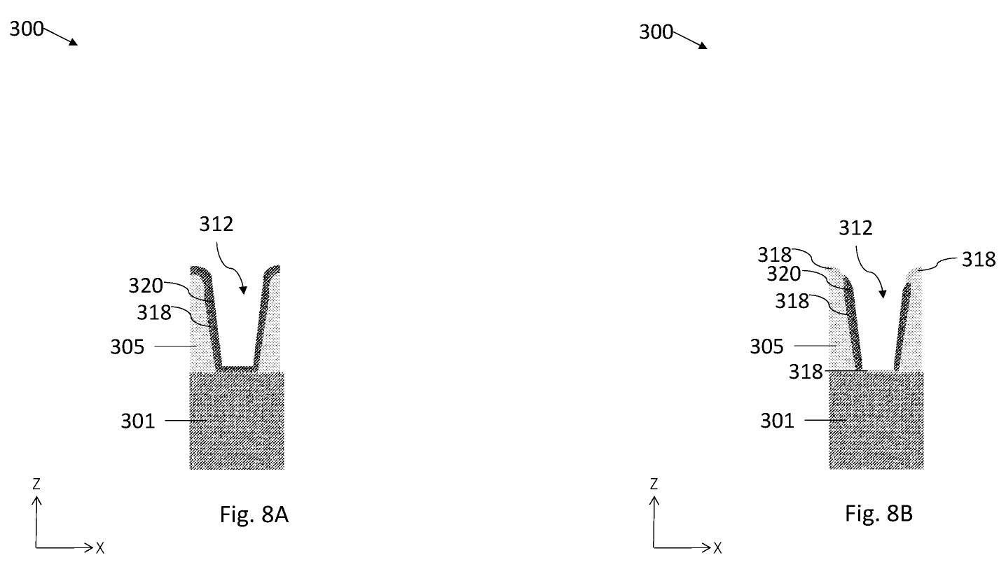

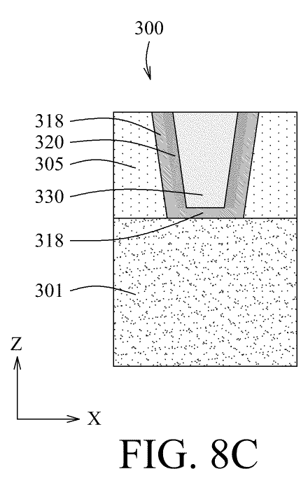

FIGS. 8A, 8B and 8C are cross-sectional side views of various stages of manufacturing the interconnection structure 300, in accordance with alternative embodiments. As shown in FIG. 8A, the first and second layers 318, 320 are formed in the opening 312 on the dielectric layer 305. In some embodiments, the second layer 320 includes the alloy nitride exposed in the opening 312 and the first layer 318 includes the alloy interfacing the dielectric layer 305. Next, an etch process is performed to remove portions of the second layer 320 formed on horizontal surfaces, as shown in FIG. 8B. In some embodiments, the etch process is a selective anisotropic etch process, and the first layer 318 is not substantially affected by the selective anisotropic etch process. In some embodiments, the etch process to remove the portions of the first layer 318 formed on the horizontal surfaces described in FIG. 7B may damage or remove the second layer 320 formed on the vertical surfaces. Thus, in order to minimize the risk of damaging the second layer 320 formed on the vertical surfaces, the first layer 318 formed on the horizontal surfaces are not removed, as shown in FIG. 8B. Next, as shown in FIG. 8C, the conductive feature 330 is formed in the opening 312. The conductive feature 330 may interface the first and second layers 318, 320, as shown in FIG. 8C. Because the electrical resistance of the first layer 318 is less than that of the second layer 320, the contact resistance is not substantially increased with the presence of the first layer 318 disposed below the conductive feature 330. After the deposition of the conductive feature 330, a planarization process, such as a CMP process, is performed to remove the portions of the conductive feature 330 and the first layer 318 formed over the dielectric layer 305.

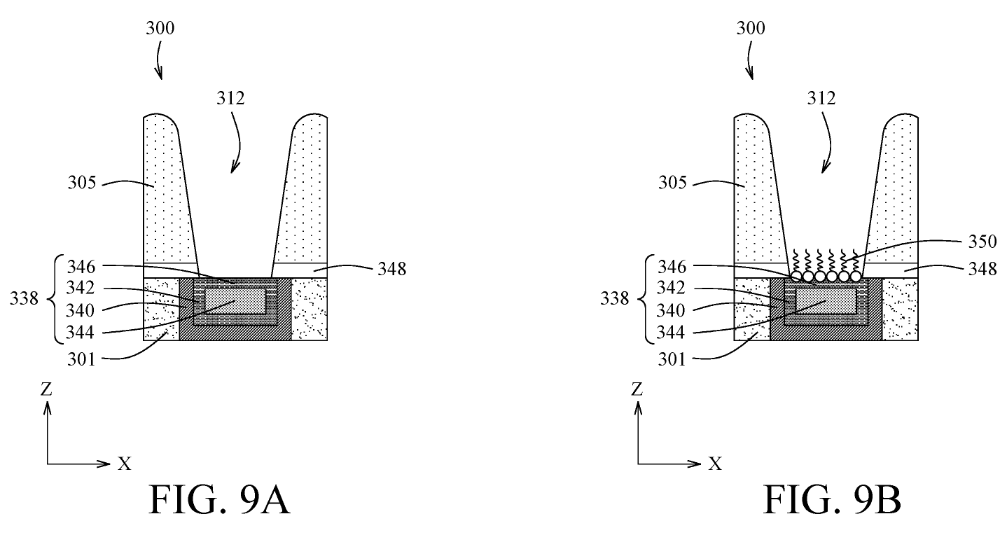

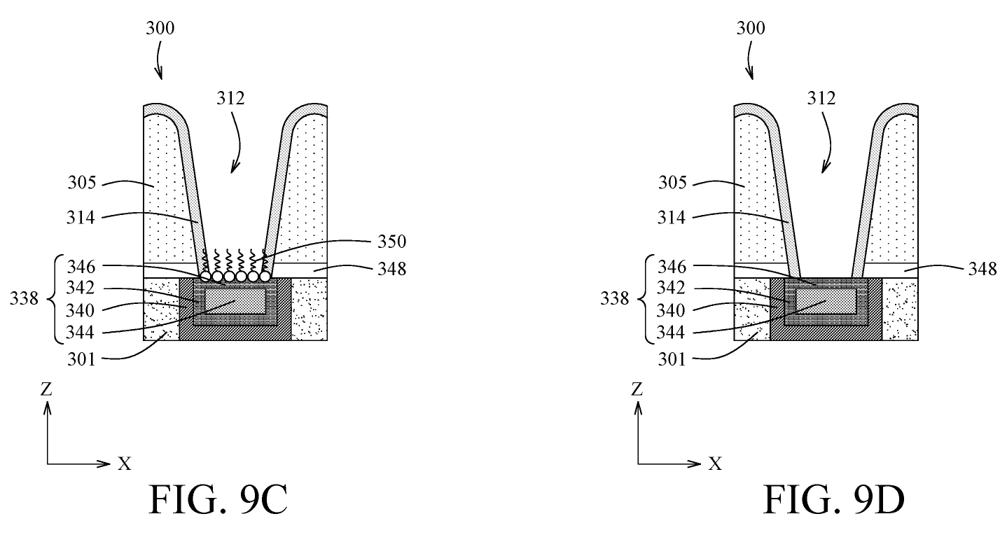

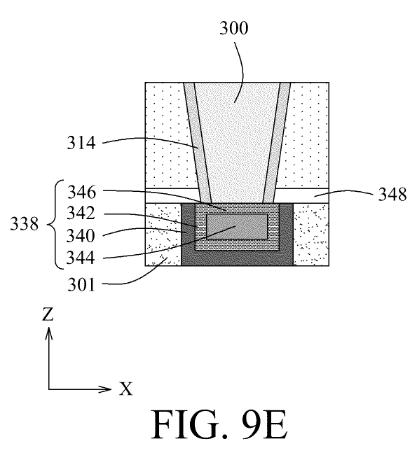

FIGS. 9A, 9B, 9C, 9D and 9E are cross-sectional side views of various stages of manufacturing the interconnection structure 300, in accordance with alternative embodiments. As shown in FIG. 9A, a conductive feature 338 is disposed in the dielectric layer 301. The conductive feature 338 may be formed in an opening formed in the dielectric layer 301. In some embodiments, the conductive feature 338 includes a barrier layer 340, a liner 342, a conductive layer 344, and a cap layer 346. The barrier layer 340 may include a material that can prevent diffusion of the metal from the conductive layer 344 into the dielectric layer 301. In some embodiments, the barrier layer 340 includes Ta, Zn, Mn, Zr, Ti, Hf, Nb, V, Cr, Sc, Y, W, Mo, Al, Ru, Mn, Co, TaNₓ, TiNₓ, WNₓ, HfOₓ, or other suitable material. The barrier layer 340 may be formed by any suitable process, such as PVD, CVD, or ALD. The liner 342 may be an adhesion layer. In some embodiments, the liner 342 includes Co, Ru, Ta, or CoRu. The liner 342 may be formed by any suitable process, such as PVD, CVD, or ALD. The conductive layer 344 may include the same material as the conductive feature 330. The conductive layer 344 may be formed by any suitable process, such as PVD, CVD, ALD, electroplating, or electroless plating. The cap layer 346 may include the same material as the liner 342. In some embodiments, after the conductive layer 344 is formed, an etch process is performed to recess the conductive layer 344, and the cap layer 346 is deposited on the recessed conductive layer 344. The cap layer 346 may be formed by any suitable process, such as PVD, CVD, or ALD.

After the formation of the conductive feature 338, an etch stop layer 348 is deposited on the dielectric layer 301 and the conductive feature 338, and the dielectric layer 305 is deposited on the etch stop layer 348. The etch stop layer 348 may include a dielectric material, such as Al₂O₃, SiCₓ, SiNₓ, SiCₓN_{y}, SiOₓN_{y}, AlOₓN_{y}, or AlNₓ, and may be doped with Hf, Zr, or Y. The etch stop layer 348 may be formed by any suitable process, such as PVD, CVD, or ALD. Next, the opening 312 is formed in the dielectric layer 305 and the etch stop layer 348 to expose the conductive feature 338, as shown in FIG. 9A. As shown in FIG. 9B, a blocking layer 350 is selectively formed on the exposed portion of the conductive feature 338. In some embodiments, the blocking layer 350 is selectively formed on the exposed cap layer 346. In some embodiments, the blocking layer 350 includes self-assembled monolayers (SAM). Examples of the SAM material may include a thiol-based compound (e.g., dodecanethiol, and/or alkanethiol), an acid-based compound (e.g., phosphonic acid, and/or octadecylphosphonic acid), a bicyclic nitrogen heterocycle compound (e.g., benzotriazole), or combinations thereof. The blocking layer 350 may be selectively formed on the metal surface of the cap layer 346 but not on the dielectric surfaces of the dielectric layer 305 and the etch stop layer 348. The blocking layer 350 may be deposited by any suitable process, such as CVD, ALD, spin coating, immersion, or combinations thereof.

Next, as shown in FIG. 9C, the composite layer 314 is selectively deposited on the dielectric layer 305 and the etch stop layer 348. The composite layer 314 may be deposited by the processes described in FIGS. 3C, 3C-1, 3C-2 and 3C-3. The blocking layer 350 prevents the composite layer 314 from being deposited thereon. As shown in FIG. 9D, the blocking layer 350 is removed. The blocking layer 350 may be removed by any suitable process, such as thermal, electrical-assisted desorption, plasma treatment, or combinations thereof. The process to remove the blocking layer 350 is a selective process that does not substantially affect the composite layer 314 and the cap layer 346. The conductive feature 330 is formed in the opening 312, as shown in FIG. 9E. In some embodiments, the conductive feature 330 is interfacing the conductive feature 338, and the contact resistance is reduced.

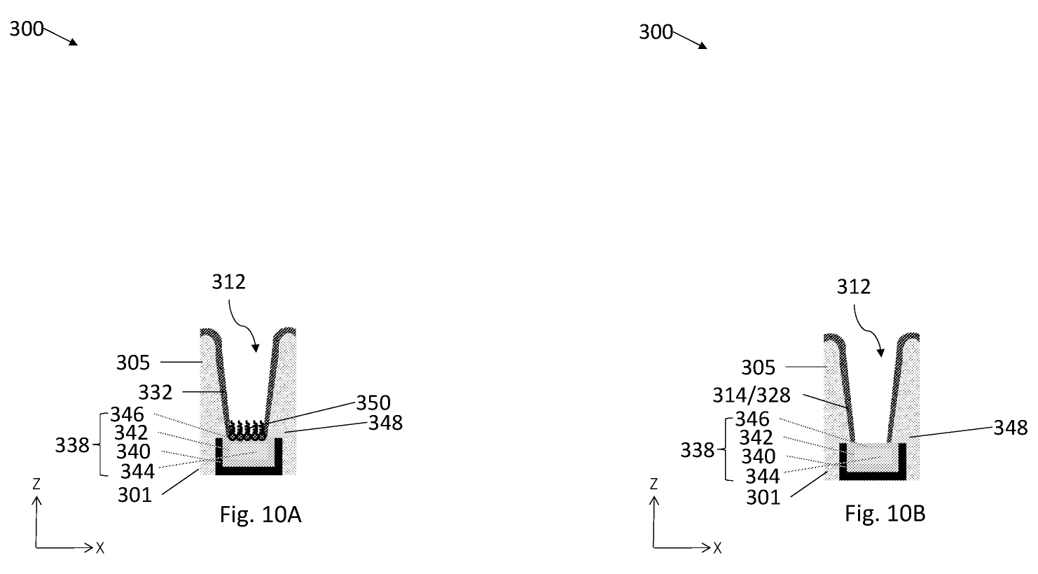

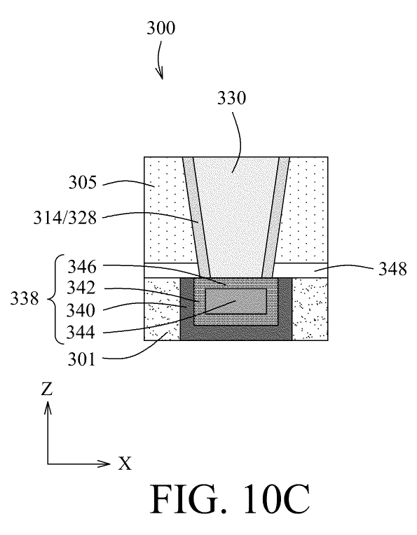

FIGS. 10A, 10B and 10C are cross-sectional side views of various stages of manufacturing the interconnection structure 300, in accordance with alternative embodiments. As shown in FIG. 10A, after forming the blocking layer 350 on the exposed cap layer 346, the alloy layer 332 is selectively deposited on the dielectric layer 305 and the etch stop layer 348. The alloy layer 332 may be deposited by the processes described in FIG. 4A. The blocking layer 350 prevents the alloy layer 332 from being deposited thereon. Next, as shown in FIG. 10B, a process is performed to simultaneously form the composite layer 314 (or the gradient layer 328) and remove the blocking layer 350. For example, in some embodiments, a nitrogen-containing plasma treatment process is performed. The nitrogen-containing plasma process partially or fully nitridizes the alloy layer 332 to form either the composite layer 314 having the alloy portion and the alloy nitride portion or the gradient layer 328. The nitrogen-containing plasma process may also remove the blocking layer 350. Next, as shown in FIG. 10C, the conductive feature 330 is formed in the opening 312.

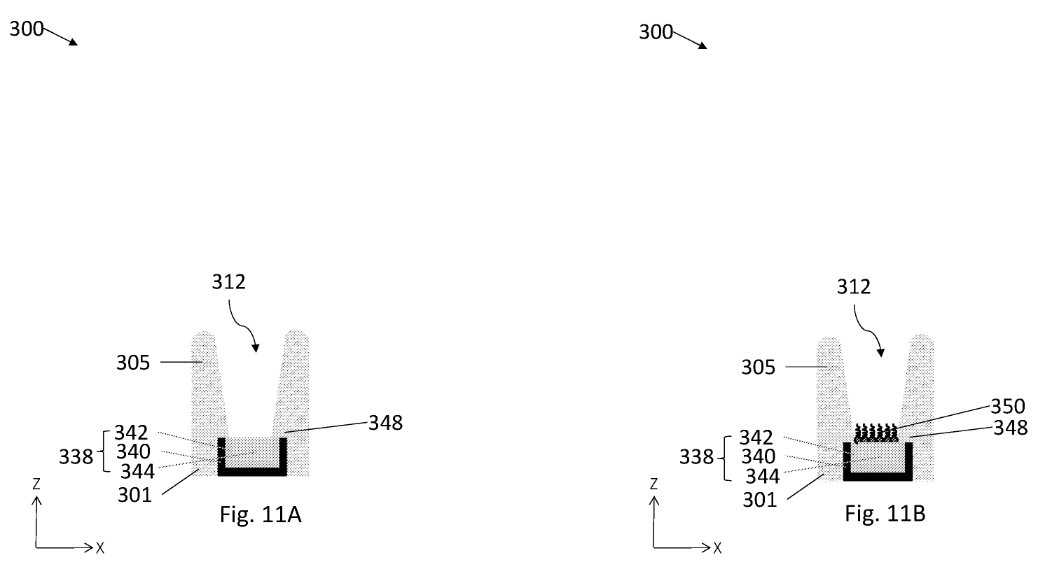

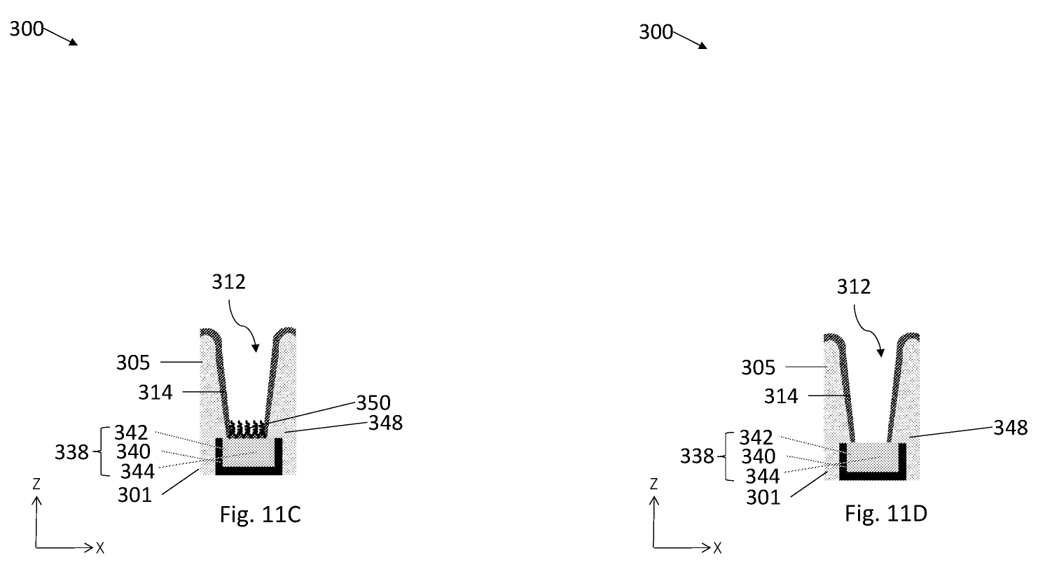

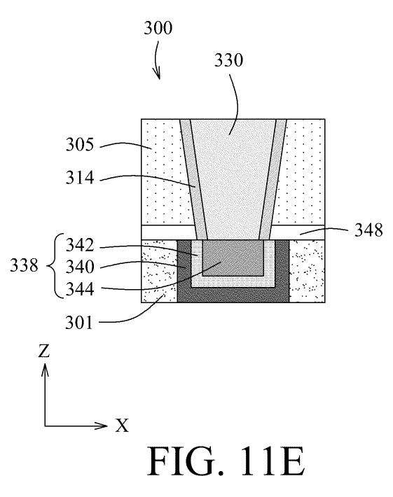

FIGS. 11A, 11B, 11C, 11D and 11E are cross-sectional side views of various stages of manufacturing the interconnection structure 300, in accordance with alternative embodiments. As shown in FIG. 11A, in some embodiments, the cap layer 346 is not present, and the conductive feature 338 includes the barrier layer 340, the liner 342, and the conductive layer 344. The conductive layer 344 is exposed at the bottom of the opening 312. Next, as shown in FIG. 11B, the blocking layer 350 is selectively formed on the exposed surface of the conductive layer 344. The blocking layer 350 may be formed on the metal surface of the conductive layer 344 but not on the dielectric surfaces of the dielectric layer 305 and the etch stop layer 348. The composite layer 314 is selectively formed on the dielectric layer 305 and the etch stop layer 348, as shown in FIG. 11C. The blocking layer 350 prevents the composite layer 314 from being deposited thereon. After the deposition of the composite layer 314, the blocking layer 350 is removed, as shown in FIG. 11D. Next, the conductive feature 330 is formed in the opening 312, as shown in FIG. 11E. In some embodiments, the conductive feature 330 is interfacing the conductive layer 344, as shown in FIG. 11E.

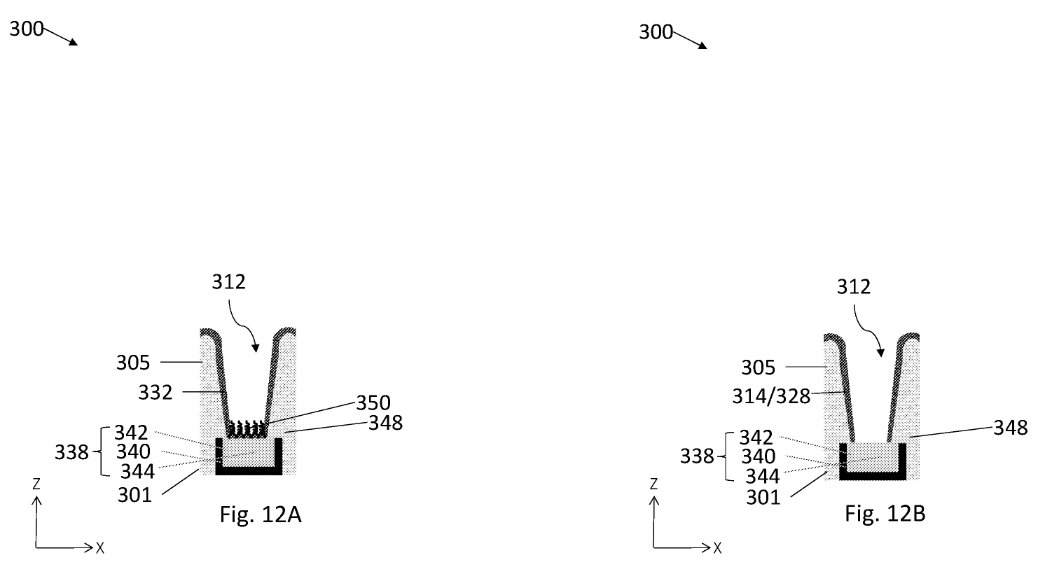

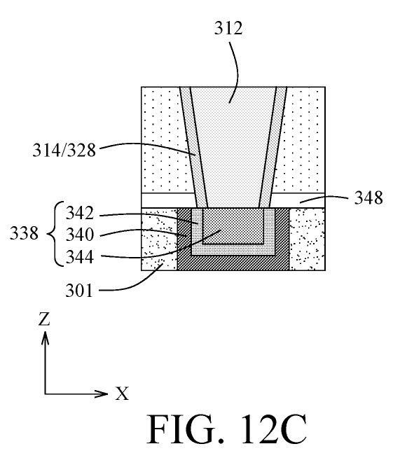

FIGS. 12A, 12B and 12C are cross-sectional side views of various stages of manufacturing the interconnection structure 300, in accordance with alternative embodiments. As shown in FIG. 12A, after forming the blocking layer 350 on the exposed conductive layer 344, the alloy layer 332 is selectively deposited on the dielectric layer 305 and the etch stop layer 348. The alloy layer 332 may be deposited by the processes described in FIG. 4A. The blocking layer 350 prevents the alloy layer 332 from being deposited thereon. Next, as shown in FIG. 12B, a process is performed to simultaneously form the composite layer 314 (or the gradient layer 328) and remove the blocking layer 350. For example, in some embodiments, a nitrogen-containing plasma treatment process is performed. The nitrogen-containing plasma process partially or fully nitridizes the alloy layer 332 to form either the composite layer 314 having the alloy portion and the alloy nitride portion or the gradient layer 328. The nitrogen-containing plasma process may also remove the blocking layer 350. Next, as shown in FIG. 12C, the conductive feature 330 is formed in the opening 312.

Various embodiments of the present disclosure provide an interconnection structure and methods of forming the same. In some embodiments, the interconnection structure includes a dielectric layer 305, a conductive feature 330 disposed in the dielectric layer 305, and a composite layer 314 disposed between the dielectric layer 305 and the conductive feature 330. The composite layer 314 may include an alloy nitride layer. Some embodiments may achieve advantages. For example, the alloy nitride layer can function as a barrier layer and an adhesion layer. The thickness of the alloy nitride layer may be small, which may lead to enlarged conductive feature 330. As a result, electrical resistance is reduced.

An embodiment is a method. The method includes depositing a first dielectric layer over a second dielectric layer, forming an opening in the first dielectric layer, and forming a composite layer on the first dielectric layer in the opening. The composite layer includes an alloy nitride. The method further includes depositing a conductive feature on the composite layer, wherein the conductive feature fills the opening.

Another embodiment is a method. The method includes depositing a first dielectric layer over a second dielectric layer forming an opening in the first dielectric layer to expose a first conductive feature in the second dielectric layer, selectively depositing a blocking layer on the first conductive feature, and forming a composite layer on the first dielectric layer in the opening. The composite layer includes an alloy nitride. The method further includes depositing a second conductive feature on the composite layer, and the second conductive feature fills the opening.

A further embodiment is a structure. The structure includes a first dielectric layer disposed over a second dielectric layer, a first conductive feature disposed in the first dielectric layer, and a composite layer disposed between the first conductive feature and the first dielectric layer. The composite layer includes an alloy nitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is :

1. A method, comprising:
depositing a first dielectric layer over a second dielectric layer;
forming an opening in the first dielectric layer;
forming a composite layer on the first dielectric layer in the opening, wherein the composite layer comprises an alloy nitride; and
depositing a conductive feature on the composite layer, wherein the conductive feature fills the opening.

2. The method of claim 1, wherein the composite layer is formed by a deposition process.

3. The method of claim 1, wherein the forming of the composite layer comprises:
depositing an alloy layer; and
nitridating the alloy layer.

4. The method of claim 3, wherein the alloy layer is partially nitridated.

5. The method of claim 3, wherein the alloy layer is completely nitridated.

6. The method of claim 3, wherein the composite layer has a nitrogen concentration that changes in a direction away from the first dielectric layer.

7. The method of claim 1, further comprising removing portions of the composite layer formed on horizontal surfaces prior to depositing the conductive feature.

8. The method of claim 7, wherein the portions of the composite layer are removed by an anisotropic etch process.

9. A method, comprising:
depositing a first dielectric layer over a second dielectric layer;
forming an opening in the first dielectric layer to expose a first conductive feature in the second dielectric layer;
selectively depositing a blocking layer on the first conductive feature;
forming a composite layer on the first dielectric layer in the opening, wherein the composite layer comprises an alloy nitride; and
depositing a second conductive feature on the composite layer, wherein the second conductive feature fills the opening.

10. The method of claim 9, further comprising removing the blocking layer after the forming of the composite layer.

11. The method of claim 9, wherein the forming of the composite layer comprises:
depositing an alloy layer; and
nitridating the alloy layer.

12. The method of claim 11, wherein the nitridating of the alloy layer is by a plasma process.

13. The method of claim 12, wherein the blocking layer is removed by the plasma process.

14. The method of claim 9, wherein the first conductive feature comprises a barrier layer, a liner, a conductive layer, and a cap layer.

15. The method of claim 14, wherein the blocking layer is selectively deposited on the cap layer.

16. An interconnection structure, comprising:
a first dielectric layer disposed over a second dielectric layer;
a first conductive feature disposed in the first dielectric layer; and
a composite layer disposed between the first conductive feature and the first dielectric layer, wherein the composite layer comprises an alloy nitride.

17. The interconnection structure of claim 16, wherein the alloy nitride comprises CoNbN, TaNbN, RuNbN, CoTaN, CoTaNbN, CoRuNbN, CoRuTaN, CoZrN, or CoVN.

18. The interconnection structure of claim 16, further comprising a second conductive feature disposed in the second dielectric layer, wherein the first conductive feature is disposed over the second conductive feature.

19. The interconnection structure of claim 16, wherein the composite layer has a thickness ranging from about 5 angstroms to about 50 angstroms.

20. The interconnection structure of claim 16, wherein the composite layer has a gradient nitrogen concentration.
